(19) United States
(12) Patent Application Publication
(10) Pub. No.: US 2009/0219457 A1
(43) Pub. Date: Sep. 3, 2009

(54) DISPLAY SUBSTRATE, METHOD FOR REPAIRING DEFECTS THEREOF AND MOTHER SUBSTRATE HAVING THE SAME

(76) Inventors: Jin-Suk SEO, Cheonan-si (KR); Hye-Rhee Han, Suwon-si (KR); Beom-Jun Kim, Seoul (KR); Young-Woon Kho, Cheonan-si (KR); Yu-Jun Kim, Seo-gu (KR)

Correspondence Address: Haynes and Boone, LLP;IP Section, 2323 Victory Avenue, SUITE 700, Dallas, TX, 75219, US

(21) Appl. No.: 12/372,676

(22) Filed: Feb. 17, 2009

(30) Foreign Application Priority Data
Mar. 3, 2008 (KR) 10-2008-0019523

(51) Int. Cl. G02F 1/133; H05K 1/16

(52) U.S. Cl. 349/55; 349/54; 349/192; 174/260

(57) ABSTRACT

A display substrate includes a source pad part, a plurality of storage wirings and a first voltage wiring. The source pad part includes a first voltage input pad receiving a storage common voltage. The storage wirings transmit the storage common voltage to a plurality of pixels. The first voltage wiring is connected to the first voltage input pad to be extended in a direction crossing the storage wirings. The first voltage wiring includes a first protrusion part overlapping a first end portion of each of the storage wirings. Therefore, defects of the display substrate may be detected by an electrical test and then repaired, and test efficiency of the display substrate may be enhanced.

### CROSS-REFERENCE TO RELATED APPLICATIONS

This application claims the benefit of priority under 35 U.S.C. §119 from Korean Patent Application No. 2008-19523, filed on Mar. 3, 2008 in the Korean Intellectual Property Office (KIPO), the contents of which are herein incorporated by reference in their entirety.

### BACKGROUND OF THE INVENTION

1. Field of the Invention

The present invention relates to a display substrate that is used in a liquid crystal display (LCD) device, a method for repairing defects in the display substrate and a mother substrate that includes at least one of the display substrates.

2. Description of the Related Art

Recently, the technology of liquid crystal display (LCD) devices has been developed in response to the various needs of consumers and to the increased need for products with superior characteristics. In order to realize high aperture ratio and high luminance, an LCD device having an organic insulation layer has been developed.

Generally, an LCD device includes an array substrate having a plurality of gate wirings, a plurality of data wirings, a plurality of storage wirings, a plurality of thin-film transistors and a plurality of pixel electrodes formed thereon. However, in an LCD device having an organic insulation layer, the organic insulation layer is relatively thick and is formed on a base substrate having gate wirings, data wirings, storage wirings and thin-film transistors formed thereon. A plurality of pixel electrodes is formed on the organic insulation layer.

The organic insulation layer decreases the intensity of an electric field between the data wirings and the pixel electrodes, so that the pixel electrodes may be positioned to overlap the data wirings. Thus, high aperture ratio and high luminance may be obtained.

Voltage wirings which apply a storage common voltage to the storage wirings are electrically connected to the storage wirings by a bridge pattern formed from the same conductive material from which the pixel electrodes are formed. End portions of the storage wirings are electrically connected with the voltage wiring through the bridge patterns and the contact holes formed through the organic insulation layer. Therefore, poor quality electrical connections, between end portions of the storage wirings and the voltage wiring, occur because of poor quality contacts between the bridge patterns and the storage wirings or because of poor quality contacts between the bridge patterns and the voltage wiring at the contact holes formed through the thick organic insulation layer. For example, a poor quality connection such as an open circuit connection between a storage wiring and the voltage wiring may be due to an open circuit contact between the bridge pattern and the storage wiring or between the bridge pattern and the voltage wiring. Therefore, a storage common voltage is not applied to the storage wirings, so that display defects such as a horizontal line detect may be generated. In an array substrate having the organic insulation layer, the horizontal line defect is associated with short circuit defects and open circuit defects of wirings, the defects being generated during manufacturing of the array substrate.

### SUMMARY OF THE INVENTION

The present invention provides a display substrate in which defects may be repaired.

The present invention also provides a method for repairing defects of the above-mentioned display substrate.

The present invention also provides a mother substrate having at least one the above-mentioned display substrates.

In one aspect of the present invention, a display substrate includes a source pad part, a plurality of storage wirings and a first voltage wiring. The source pad part includes a first voltage input pad for receiving a storage common voltage. The storage wirings transmit the storage common voltage to a plurality of pixels. The first voltage wiring is connected to the first voltage input pad and extends in a direction crossing the storage wirings. The first voltage wiring includes a first protrusion part overlapped with a first end portion of each of the storage wirings.

In another aspect of the present invention, there is provided a method for repairing defects of a display substrate including a plurality of storage wirings formed in a plurality of pixels and a voltage wiring connected to a voltage input pad and extended in a direction crossing the storage wirings. In the above-mentioned method, a poor quality contact between the storage wirings and the voltage wiring is detected by applying a test signal to the voltage input pad. Then, an end portion of a storage wiring where the poor quality contact is detected and a protrusion part of the voltage wiring which is overlapped with an end portion of each of the storage wirings are intentionally shorted.

In still another aspect of the present invention, a mother substrate includes a display cell, a guard ring, a first voltage test wiring, a voltage test pad and a second voltage test wiring. The display cell includes a source pad part including first and second voltage input pads receiving a storage common voltage, a plurality of storage wirings transmitting the storage common voltage to a plurality of pixels, a first voltage wiring connected to the first voltage input pad and extended in a direction crossing the storage wirings, the first voltage wiring including a first protrusion part overlapping a first end portion of each storage wirings, and a second voltage wiring connected to the second voltage input pad, the second voltage wiring including a second protrusion part overlapping a second end portion of each of storage wirings. The guard ring is formed to surround the display cell to prevent static electricity from inflowing to the display cell. The first voltage test wiring connects the first voltage input pad and the guard ring. The voltage test pad is connected to the guard ring to receive a test signal. The second voltage test wiring connects the voltage test pad to the second voltage input pad.

According to a method for repairing defects of the display substrate and a mother substrate having the display substrate, defects of the display substrate may be repaired, and test efficiency of the display substrate may be enhanced.

### BRIEF DESCRIPTION OF THE DRAWINGS

The above and other advantages of the present invention will become readily apparent by reference to the following detailed description when considered in conjunction with the accompanying drawings wherein:

FIG. 1 is a plan view illustrating a mother substrate according to an embodiment of the present invention;

FIG. 2 is a plan view illustrating two paths by which a test signal is transmitted to a display substrate of FIG. 1;

FIG. 3 is a partial plan view illustrating a display substrate of FIG. 1;

FIG. 4 is a cross-sectional view taken along a line I-I′ of FIG. 3;

FIG. 5 is a plan view illustrating a repaired display substrate of FIG. 3; and

FIG. 6 is a cross-sectional view taken along a line II-II′ of FIG. 5.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

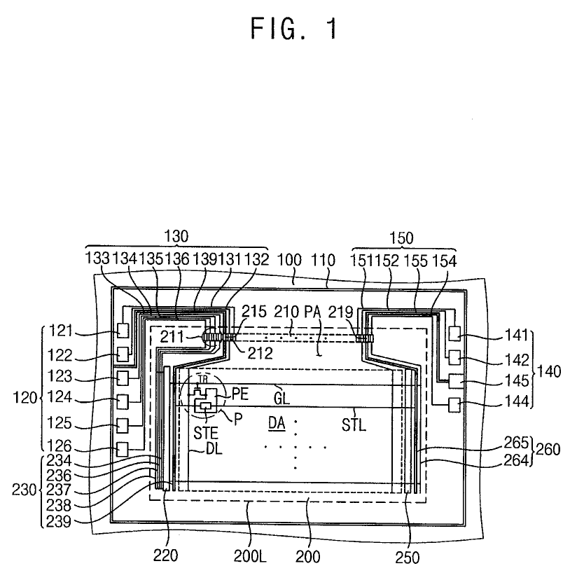

FIG. 1 is a plan view illustrating a mother substrate according to an embodiment of the present invention.

Referring to FIG. 1, a mother substrate 100 includes at least one display cell 200, a guard ring 110, a first test pad part 120, a first test wiring part 130, a second test pad part 140 and a second test wiring part 150.

The lateral dimensions of the display cell 200 are defined by a cutting line 200L formed on the mother substrate 100. The display cell 200 includes a display area DA having a plurality of pixels P formed thereon and a peripheral area PA that surrounds the display area DA. Hereinafter, the display cell 200 may be referred to as a display substrate.

A plurality of data wirings DL, a plurality of gate wirings GL crossing the data wirings DL, and a plurality of storage wirings STL for transmitting a storage common voltage Vst to storage electrodes STE are formed in the display area DA. Hereinafter, the storage common voltage Vst may be referred to as a common voltage. Each of the pixels P includes a switching element TR electrically connected to a data wiring DL and to a gate wiring GL, a pixel electrode PE electrically connected to the switching element TR, and a storage electrode STE that is overlapped by the pixel electrode PE.

A source pad part 210, a gate drive circuit 220, a first connecting wiring part 230, an auxiliary drive circuit 250 and a second connecting wiring part 260 are formed on the peripheral area PA.

The source pad part 210 includes a plurality of input pads 211 for receiving driving signals from an external device and a plurality of output pads 212 for outputting a plurality of data signals to the data wirings DL. For example, the source pad part 210 includes input pads 211 and first and second voltage input pads 215 and 219. Here, the input pads 211 receive gate driving signals for driving the gate drive circuit 220, the gate driving signals including a vertical start signal STV, clock signals CK and CKB and a voltage signal VSS. The first and second voltage input pads 215 and 219 receive the common voltage Vst that is to be applied to the storage electrodes STE.

The gate drive circuit 220 receives the gate driving signals from the input pads 211, generates gate signals by using the gate driving signals, and outputs a high voltage to the gate wirings GL, sequentially. For example, the gate drive circuit 220 includes a shift register having a plurality of stages that are connected to each other in a cascade type arrangement. The gate drive circuit 220 is electrically connected to a plurality of first terminals of the gate wirings GL. In this embodiment, the gate drive circuit 220 is directly integrated in the display substrate 200. Alternatively, the gate drive circuit may be an integrated circuit chip that is mounted on the display substrate 200. In the latter case, a plurality of pads, to which terminals of the gate drive integrated circuit chip are attached, may be formed on the display substrate 200.

The first connecting wiring part 230 includes a first signal wiring 234, a second signal wiring 236, a third signal wiring 237 and a fourth signal wiring 238 that are connected to corresponding input pads 211 that receive the gate driving signals. The first to fourth signal wirings 234, 236, 237 and 238 transmit the gate driving signals to the gate drive circuit 220. The first connecting wiring part 230 further includes a first voltage wiring 239 that is connected to first end portions of the storage wirings STL to transmit the common voltage Vst to the storage electrodes STE in the pixels P of the display area DA. The first voltage wiring 239 is connected to the first voltage input pad 215 and is extended substantially parallel with the data wiring DL.

The auxiliary drive circuit 250 is connected to second end terminals of the gate wirings GL, so that the gate wirings GL are maintained a low voltage level. For example, a high voltage level is applied to each of the gate wirings for 1H, wherein ‘H’ is a horizontal period, and then a low voltage level is maintained. That is, when a high voltage level is applied to (n+1)-th gate wiring, the auxiliary drive circuit 250 pulls down (n)-th gate wiring so that the (n)-th gate wiring is maintained at a low voltage level for one frame interval.

The second connecting wiring part 260 includes a fifth signal wiring 264 for transmitting a gate driving signal to the auxiliary drive circuit 250, the fifth signal wiring 264 being connected to an input pad for receiving the gate driving signal, for example, a voltage signal VSS. The second connecting wiring part 260 further includes a second voltage wiring 265 electrically connected to second end portions of the storage wirings STL to transmit the common voltage Vst to storage electrodes STE in the pixels P in the display area DA. The second voltage wiring 265 is connected to the second voltage input pad 219.

The guard ring 110 is formed to surround the display substrate 200. The guard ring 110 may prevent static electricity generated in a manufacturing process of the display substrate 200 from inflowing to the display substrate 200.

The first test pad part 120 receives test signals for testing short and open defects in the data wirings DL, the gate wirings GL and the storage wirings STL formed on the display substrate 200. For example, the first test pad part 120 includes first and second test pads 121 and 122 for receiving test signals that are to be applied to the data wirings DL, and further includes third, fourth, fifth and sixth test pads 123, 124, 125 and 126 for receiving test signals that are to be applied in place of driving signals STV, CK, CKB and VSS to the gate drive circuit 220. The first test pad 121 applies a test signal to odd-numbered data wirings, and the second test pad 122 applies a test signal to even-numbered data wirings. For example, the test signal applied to the odd-numbered data wirings may be different from the test signal applied to the even-numbered data wirings.

The first test wiring part 130 connects the first test pad part 120 to the source pad part 210 to transmit the test signals from the first test pad part 120 to the data wirings DL and the gate drive circuit 220 of the display substrate 200. The first test wiring part 130 includes first, second, third, fourth, fifth and sixth test wirings 131, 132, 133, 134, 135 and 136 which connect the first, second, third, fourth, fifth and sixth test pads 121, 122, 123, 124, 125 and 126 to the input pads 211 of the source pad part 210.

Moreover, the first test wiring part 130 further includes a first voltage test wiring 139 that connects the first voltage input pad 215 to the guard ring 110.

The second test pad part 140 receives test signals that are used for testing for short and open defects in the data wirings DL and in the storage wirings STL formed on the display substrate 200. For example, the second test pad part 140 includes seventh and eight test pads 141 and 142 for receiving test signals corresponding to the data lines DL, and a ninth test pad 144 for receiving a test signal corresponding to a voltage signal VSS for driving the auxiliary drive circuit 250. The seventh test pad 141 is connected to odd-numbered data wirings to transmit a test signal to the odd-numbered data wirings, and the eighth test pad 142 is connected to even-numbered data wirings to transmit a test signal to the even-numbered data wirings.

The second test pad part 140 further includes a voltage test pad 145 for receiving the common voltage Vst. The voltage test pad 145 is electrically connected to the guard ring 110.

The second test wiring part 150 connects the second test pad part 140 to the source pad part 210 to transmit test signals from the second test pad part 140 to the data wirings DL and to the second voltage wiring 265 of the display substrate 200. The second test wiring part 150 includes seventh, eighth and ninth test wirings 151, 152 and 154 that connect the seventh, eighth and ninth test pads 141, 142 and 144 to the input pads of the source pad part 210. Moreover, the second test wiring part 150 further includes a second voltage test wiring 155 connecting the voltage test pad 145 to the second voltage input pad 219.

As a result, the common voltage Vst, that is used here as a test signal, is received from the voltage test pad 145, and is transmitted to the second voltage wiring 265 through the second voltage test wiring 155 and the second voltage input pad 219. Moreover, the common voltage Vst is transmitted to the first voltage wiring 239 via the first voltage test wiring 139 and the first voltage input pad 215 through the guard ring 110 which is electrically connected to the voltage test pad 145.

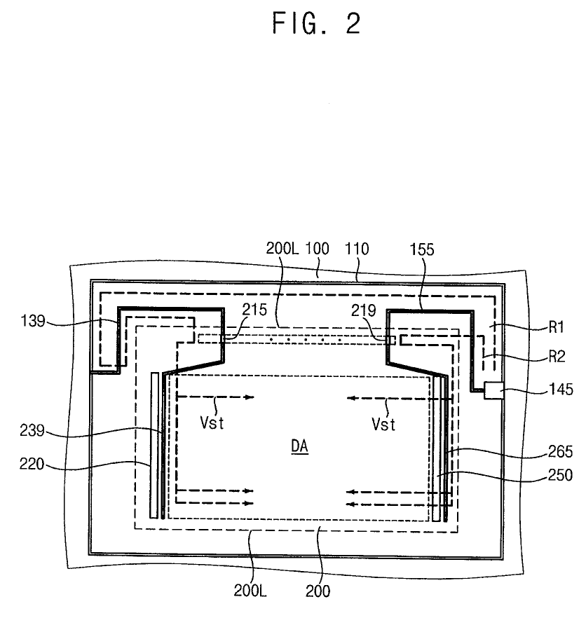

FIG. 2 is a plan view illustrating paths by which a test signal is transmitted to a display substrate of FIG. 1.

Referring to FIG. 2, first and second voltage input pads 215 and 219 formed in the display substrate 200 receive the common voltage Vst from the voltage test pad 145. The first voltage input pad 215 is connected to the first voltage wiring 239 formed at a first side of the display substrate 200. The second voltage input pad 219 and the first voltage input pad 215 are formed in a symmetric structure. The second voltage input pad 219 is connected to the second voltage wiring 265 formed at a second side of the display substrate 200. The second side of the display substrate 200 may face the first side of the display substrate 200 with the display area DA being located between the first side and the second side.

The guard ring 110 is formed in an area outside the cutting line 200L of the display substrate 200 and surrounds the display substrate 200.

The second test wiring 155 is connected to the second voltage input pad 219 and is formed in an area between the display substrate 200 and the guard ring 110. The voltage test pad 145 which is used for receiving a test signal, such as the common voltage Vst, is formed at an end portion of the second voltage test wiring 155. The voltage test pad 145 is electrically connected to the guard ring 110. For example, when the voltage test pad 145 and the guard ring 110 are formed from the same conductive layer, the voltage test pad 145 may extend from the guard ring 110 and thus be connected to the guard ring 110. However, when the voltage test pad 145 and the guard ring 110 are formed from the different conductive layers, the voltage test pad 145 and the guard ring 110 may be connected by a bridge pattern through a contact hole or contact holes.

The first voltage input pad 215 is connected to the first voltage test wiring 139. The first voltage test wiring 139 is electrically connected to the guard ring 110. For example, when the first voltage test wiring 139 and the guard ring 110 are formed from the same conductive layer, the first voltage test wiring 139 may be extended to and thus be connected to the guard ring 110. Alternatively, when the first voltage test wiring 139 and the guard ring 110 are formed from two different conductive layers, the first voltage test wiring 139 and the guard ring 110 may be connected by a bridge pattern through a contact hole or contact holes.

When the voltage test pad 145 receives a test signal, such as the common voltage Vst, the common voltage Vst is transmitted to the display substrate 200 through a first path R1 and a second path R2.

The second path R2 is a path which passes through the voltage test pad 145, the second voltage test wiring 155, the second voltage input pad 219 and the second voltage wiring 265. Thus the common voltage Vst is applied from a second side of the display area DA to the storage electrodes in the pixels through the second path R2.

The first path R1 is a path which passes through the voltage test pad 145, the guard ring 110, the first voltage test wiring 139, the first voltage input pad 215 and the first voltage wiring 239. Thus the common voltage Vst is applied from a first side of the display area DA to the storage electrodes STE in the pixels through the first path R1.

As a result, the common voltage Vst is uniformly applied as a test voltage from two sides of the display area DA to the storage electrodes STE in the pixels by using the guard ring 110, so that defects that give rise to visual defects such as a horizontal line defect may be detected during an array test process. Therefore, an efficiency of an array test process for the display substrate 200 may be enhanced.

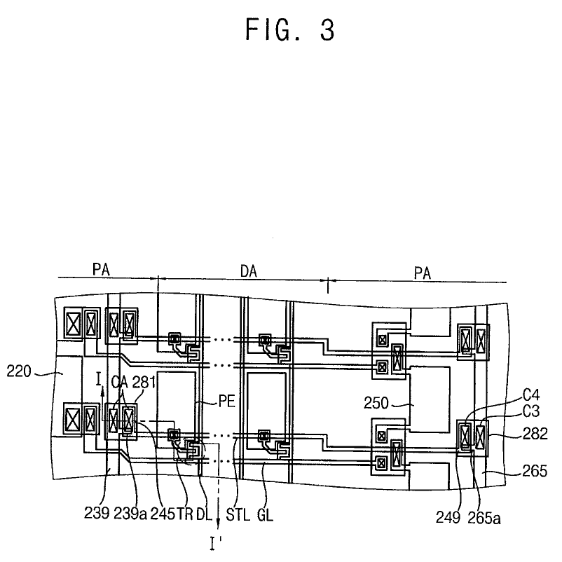

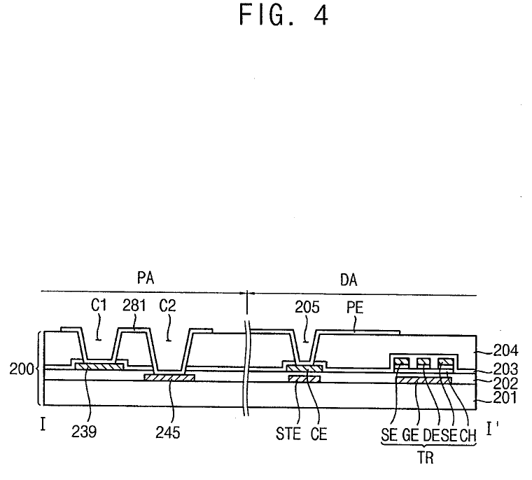

FIG. 3 is a partial plan view illustrating a display substrate of FIG. 1. FIG. 4 is a cross-sectional view taken along a line I-I′ of FIG. 3.

Referring to FIGS. 1, 3 and 4, a display substrate 200 includes a base substrate 201 including a display area DA and a peripheral area PA. The data wirings DL, the gate wirings GL, the storage wirings STL, the switching elements TR, and the pixel electrode PE are formed in the display area DA. The gate drive circuit 220, the first voltage wiring 239, the auxiliary drive circuit 250, and the second voltage wiring 265 are formed in the peripheral area PA.

A first conductive pattern, including a gate wiring GL, a gate electrode GE, a storage wiring STL and a storage electrode STE is formed in a first conductive layer on the display area DA of the base substrate 201. The gate electrode GE is connected to the gate wiring GL, and the storage electrode STE is connected to the storage wiring STL. A first insulation layer 202 is formed on the base substrate 201 and on the first conductive pattern formed thereon. A channel layer CH is formed on the first insulation layer 202 in an area corresponding to the gate electrode GE. The channel layer CH includes a semiconductor layer and an ohmic contact layer. The semiconductor layer provides a channel through which a current flows in the switching element TR. The ohmic contact layer decreases a contact resistance between the semiconductor layer and source and drain electrodes SE and DE. For example, the semiconductor layer may be amorphous silicon (“a-Si”). The ohmic contact layer may include N+amorphous silicon (“n+a-Si”) that is formed by implanting N+ impurities having a high concentration. For example, phosphorous (P) may be implanted into an upper portion of the semiconductor layer to form the ohmic contact layer. The ohmic contact layer is partially removed so that the semiconductor layer is partially exposed. A second conductive pattern including a data wiring DL, a source electrode SE, a drain electrode DE and a contact electrode CE is formed in a second conductive layer deposited on the base substrate 201 having the channel layer CH formed thereon. The source electrode SE is connected to the data wiring DL, and the contact electrode CE is connected to the drain electrode DE. A second insulation layer 201 is formed on the base substrate 201 having the second conductive pattern formed thereon. A thick organic insulation layer 204, having a thickness of about 3 micrometers which allows high aperture ratio and high luminance to be realized, is formed on the second insulation layer 203. A contact hole 205 is formed through the organic insulation layer 204 and the second insulation layer 203. A third conductive pattern, including the pixel electrode PE, is formed in a third conductive layer that is deposited on the organic insulation layer. The pixel electrode makes contact with the contact electrode CE through the contact hole 205 formed in the organic insulation layer 204.

The first voltage wiring 239 is formed adjacent to the gate drive circuit 220 in the peripheral area PA, and the second voltage wiring 265 is formed adjacent to the auxiliary drive circuit 250. For example, the first and second voltage wirings 239 and 265 may be in the second conductive pattern. A first end portion 245 of the storage wiring STL is formed at an area adjacent to the first voltage wiring 239, and a second end portion 249 of the storage wiring STL is formed in an area adjacent to the second voltage wiring 265.

The first voltage wiring 239 includes a plurality of first protrusion parts 239a. Each first protrusion part 239a protrudes from the voltage wiring 239 toward a corresponding first end portion 245 and overlaps a portion of the corresponding first end portion 245. The second voltage wiring 265 includes a plurality of second protrusion parts 265a. Each second protrusion part 265a protrudes from the second voltage wiring toward a corresponding second end portion 249 and overlaps a portion of the corresponding second end portion 249.

A plurality of first contact holes C1 is formed through the organic insulation layer 204 and the second insulation layer 203 to the first voltage wiring 239. A plurality of second contact holes C2 is formed through the organic insulation layer 204, the second insulation layer 203 and the first insulation layer 202 to the first end portions 245. A plurality of first bridge patterns 281 is formed, wherein each bridge pattern 281 electrically connects the first voltage wiring 265 to a corresponding first end portion 245 through a first contact hole C1 and a second contact hole C2, respectively.

A plurality of contact holes C3 and C4 is formed to expose portions the second voltage wiring 265 and to expose portions the second end portions 249, respectively, and a plurality of second bridge patterns 282 electrically connects the second voltage wiring 265 to the second end portions 249 through the contact holes C3 and C4, respectively. The first and second bridge patterns 281 and 282 may, for example, be in the third conductive pattern formed in a third conductive layer.

In the first contact hole C1, an electrical contact is formed between the first bridge pattern 281 and the first voltage wiring 239. In the second contact hole, an electrical contact is formed between the first bridge pattern 281 and a first end portion 245 of a storage line STL. The first contact, together with the second contact, provides an electrical connection between the first voltage wiring 239 and a storage line STL. If either the first contact or the second contact is defective, then the electrical connection between the first wiring 239 and the storage line STL is also defective. A defective contact is a contact that is either open circuit or is resistive. A defective contact that is open circuit may be called an open defect.

Here, the contact holes C1, C2, C3, and C4 are formed by removing portions of the organic insulation layer 204, and the first and second insulation layers 202 and 203. As the organic insulation layer 204 is thick, with the thickness being about 3 micrometers, a large step, about 3 micrometers deep, is formed at the contact holes C1, C2, C3, and C4. Open defects and resistive contacts may occur at the deep contact holes C1, C2, C3, and C4. Thus the first and second bridge patterns 281 and 282 may fail to provide a good connection between the first and second voltage wirings 239 and 265 and the first and second end portions 245 and 249, respectively. The open defects may be observed as horizontal line defects in a displayed image.

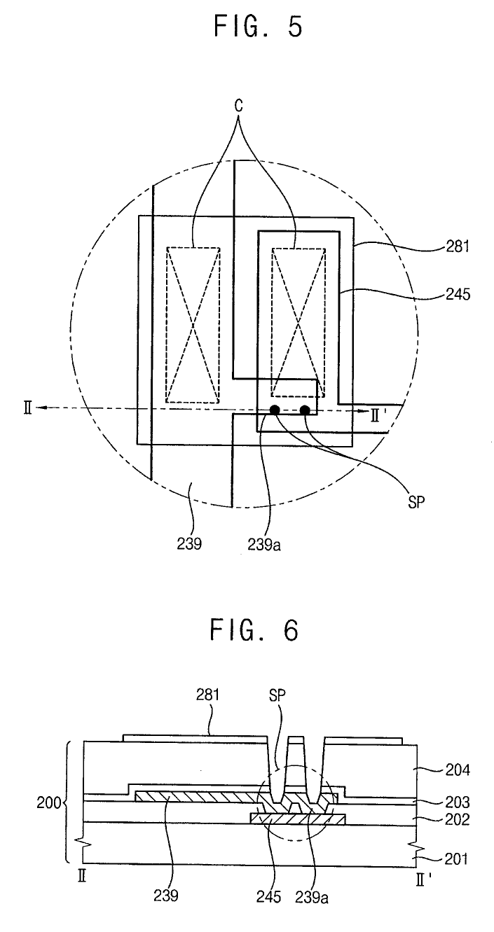

When, in accordance with the present invention, open defects or resistive contacts at the first and second bridge patterns 281 and 282 are detected by an array test, these defects are repaired by a repairing method that is described with reference to FIGS. 5 and 6.

FIG. 5 is a plan view illustrating a repaired display substrate of FIG. 3. FIG. 6 is a cross-sectional view taken along a line II-II′ of FIG. 5.

In FIGS. 5 and 6, the first voltage wiring 239, a first end portion 245 of a storage wiring STL, and a first bridge pattern 281 are shown. The first voltage wiring 239 includes a first protrusion part 239a that protrudes from the first voltage wiring 239 towards the first end portion 245. The first protrusion part 239a overlaps a portion of the first end portion 245. The first contact hole C1 is located above the first voltage wiring 239. The second contact hole C2 is located above the first end portion 245 and also exposes a portion of the protrusion part 239a. The first bridge pattern 281 contacts the first voltage wiring 239 through the first contact hole C1 and contacts the end portion 245 through the second contact hole C2. A laser beam may be used to make the short points SP. Two short points SP are shown, however, the number of short points SP is not limited to two. At each short point, the laser beam has removed a portion of the bridge pattern 281, a portion of the organic insulation layer 204, and a portion of the second insulation layer 203, and has disrupted the first insulation layer 202 and formed a contact between the first protrusion part 239a and the first end portion 245. The short points SP provide an electrical connection between the first voltage wiring 239 and the storage wiring STL that bypasses the contacts formed at contact holes C1 and C2.

Referring to FIGS. 1, 3, 5 and 6, a test for the display substrate 200 that is cut from the mother substrate 100 is preformed by a display cell. A test signal is applied to the source pad part 210 formed in the display substrate 200 to detect poor contact or defects in accordance with a driving of the display substrate 200. When poor contacts between the first and second voltage wirings 239 and 265 and the first and second end portions 245 and 249 of the storage wirings STL or open defects of the first and second bridge patterns 281 and 282 are detected, a repair may be performed as follows.

The first protrusion part 239a of the first voltage wiring 239 and the first end portion 245 of the storage wiring STL are intentionally shorted by a laser beam, so that a short point SP is formed at the first protrusion part 239a. Accordingly, the first voltage wiring 239 and the first end portion 245 of the storage wiring STL are intentionally shorted, so that the common voltage Vst may be applied to the storage wiring STL.

When defects are present between the second voltage wiring 265 and the second end portion 249 of the storage wiring STL, the short point SP is formed at the second protrusion part 265a of the second voltage wiring 265, so that defects may be repaired.

According to embodiments of the present invention, in a liquid crystal display, a horizontal line defect which may arise due to a defective contact which prevents a common voltage from being applied to the storage wirings, may be prevented. For example, the common voltage is applied as a test signal to two end portions of storage wirings on the display substrate by using the guard ring located on the mother substrate, so that array test efficiency may be enhanced. Moreover, a protrusion part of the voltage wiring is formed to overlap the end portion of the storage wiring, so that the storage wiring may be intentionally shorted to the protrusion part when defects are present in a bridging pattern between the storage wiring and the voltage wiring, so that defects may be repaired. Thus, display defects such as the horizontal line defects may be prevented.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A display substrate comprising:
a source pad part comprising a first voltage input pad, the first voltage input pad receiving a storage common voltage;
a plurality of storage wirings transmitting the storage common voltage to a plurality of pixels; and
a first voltage wiring connected to the first voltage input pad, the first voltage wiring extending in a direction crossing the storage wirings, the first voltage wiring comprising a first protrusion part overlapping a first end portion of each of the storage wirings.

2. The display substrate of claim 1, wherein each of the pixels comprises:
a switching element connected to a gate wiring and to a data wiring, the data wiring crossing the gate wiring;
a pixel electrode connected to the switching element; and
a storage electrode overlapped by the pixel electrode, the storage electrode being electrically connected to the storage wiring.

3. The display substrate of claim 2, further comprising an organic insulation layer formed between the switching element and the pixel electrode.

4. The display substrate of claim 2, wherein the storage wiring and the gate wiring are substantially parallel to each other.

5. The display substrate of claim 2, further comprising a gate drive circuit formed in a peripheral area surrounding a display area having the pixels formed thereon, the gate drive circuit being connected to a first end portion of the gate wiring, the gate drive circuit outputting a gate signal to the gate wiring.

6. The display substrate of claim 5, wherein the first voltage wiring is formed in an area between the gate drive circuit and the display area and is substantially parallel to the data wiring.

7. The display substrate of claim 5, wherein the source pad part further comprises:
an input pad receiving a driving signal driving the gate drive circuit; and
an output pad outputting a data signal to the data wiring.

8. The display substrate of claim 5, wherein the source pad part further comprises a second voltage input pad formed in symmetry with the first voltage input pad to receive the storage common voltage.

9. The display substrate of claim 8, further comprising a second voltage wiring connected to the second voltage input pad, the second voltage wiring including a second protrusion part overlapping a second end portion of each of storage wirings.

10. The display substrate of claim 9, further comprising an auxiliary drive circuit connected to a second end portion of the gate wiring,
wherein the second voltage wiring is formed on the peripheral area adjacent to the auxiliary drive circuit.

11. A method for repairing defects of a display substrate comprising a plurality of storage wirings formed in a plurality of pixels and a voltage wiring connected to a voltage input pad and extending in a direction crossing the storage wirings, the method comprising:
detecting a poor contact between the storage wirings and the voltage wiring by applying a test signal to the voltage input pad; and
intentionally shorting an end portion of a storage wiring, where the poor contact is detected, to a protrusion part of the voltage wiring which is overlapped with an end portion of each of the storage wirings.

12. The method of claim 11, wherein intentionally shorting an end portion to a protrusion part is performed by using a laser beam.

13. A mother substrate comprising:
a display cell comprising a source pad part comprising first and second voltage input pads receiving a storage common voltage, a plurality of storage wirings transmitting the storage common voltage to a plurality of pixels, a first voltage wiring connected to the first voltage input pad, the first voltage wiring extending in a direction crossing the storage wirings, the first voltage wiring comprising a first protrusion part overlapping a first end portion of each storage wirings, and a second voltage wiring being connected to the second voltage input pad, the second voltage wiring including a second protrusion part overlapping a second end portion of each of storage wirings;
a guard ring formed to surround the display cell to prevent static electricity from inflowing to the display cell;
a first voltage test wiring connecting the first voltage input pad and the guard ring;
a voltage test pad connected to the guard ring to receive a test signal; and
a second voltage test wiring connecting the voltage test pad to the second voltage input pad.

14. The mother substrate of claim 13, wherein the voltage test pad is formed in an area between the display cell and the guard ring.

15. The mother substrate of claim 13, wherein each of the pixels comprises:
a switching element connected to a gate wiring and to a data wiring, the data wiring crossing the gate wiring;
a pixel electrode connected to the switching element; and
a storage electrode overlapped by the pixel electrode, the storage electrode being electrically connected to the storage wiring.

16. The mother substrate of claim 15, further comprising an organic insulation layer formed between the switching element and the pixel electrode.

17. The mother substrate of claim 15, wherein the storage wiring and the gate wiring are substantially parallel to each other.

18. The mother substrate of claim 17, further comprising a gate drive circuit being formed in a peripheral area surrounding a display area having the pixels formed thereon, the gate drive circuit being connected to a first end portion of the gate wiring, the gate drive circuit outputting a gate signal to the gate wiring.

19. The mother substrate of claim 18, wherein the first voltage wiring is formed in an area between the gate drive circuit and the display area, the first voltage wiring being substantially parallel to the data wiring.

20. The mother substrate of claim 19, wherein the second voltage wiring is substantially parallel to the first voltage wiring in the peripheral area adjacent to a second end portion of the gate wiring.
